(19) United States
(12) Patent Application Publication
(10) Pub. No.: US 2026/0167001 A1
(43) Pub. Date: Jun. 18, 2026

(54) SMART TURN-OFF LOGIC FOR HIGH POWER CONVERTERS AND INVERTERS

(71) Applicant: Cummins Power Generation Inc., Minneapolis, MN (US)

(72) Inventors: Latif M. Shaikh, Pune (IN); Anand Narayan Jarudkar, Pune (IN); Amit Balkrishna Sonpethkar, Pune (IN); Sushant Petare, Pune (IN); Vysakh M, Alappuzha (IN)

(73) Assignee: Cummins Power Generation Inc., Minneapolis, MN (US)

(21) Appl. No.: 19/128,509

(22) PCT Filed: Nov. 10, 2023
(86) PCT No.: PCT/US2023/079413

§ 371 Date: May 8, 2025

(30) Foreign Application Priority Data
Nov. 11, 2022 (IN) 202241064744

(51) Int. Cl. B60L 3/00; B60L 13/00; H02M 7/00; H03K 7/08

(52) U.S. Cl. CPC B60L 3/003; B60L 13/006; H02M 7/003; H03K 7/08; B60L 2200/26; B60L 2210/30; B60L 2210/40; B60L 2240/525; B60L 2240/527; B60L 2270/20

(57) ABSTRACT

Presented herein are systems, apparatuses, devices, and methods for deactivating high power converters and inverters in shutdown and fault events. An apparatus can include an inverter electrically coupled with a power supply. The inverter can provide electrical power from the power supply. The apparatus can include an output contactor electrically coupled with the inverter and with a load. The output contactor can pass the electrical power from the inverter to the load. The apparatus can include a controller having at least one processor coupled with memory. The controller can detect that the output contactor is off. The controller can perform, responsive to the detection, a removal of residual heat from the inverter. The controller can determine whether a temperature of the inverter is not below a threshold from performing the removal. The controller can execute at least one fault countermeasure in accordance with the determination.

### CROSS REFERENCE TO RELATED APPLICATIONS

The present application claims the benefit of priority to Indian Provisional Patent Application Number 202241064744, titled “SMART TURN OFF LOGIC FOR HIGH POWER CONVERTERS AND INVERTERS,” filed Nov. 11, 2022, which is incorporated by reference in its entirety.

### BACKGROUND

The present disclosure relates generally to converters and inverters. More specifically, the present disclosure relates to controller logic for systematically deactivating converters and inverters.

### SUMMARY

Aspects of the present disclosure relate to systems, devices, apparatuses, and methods of deactivating converters and inverters (e.g., hotel load converters used in railway applications) in shutdown and fault events. An apparatus can include an inverter structured to be electrically coupled with a power supply. The inverter can provide electrical power from the power supply. The apparatus can include an output contactor structured to be electrically coupled with the inverter and with a load. The output contactor can pass the electrical power from the inverter to the load. The apparatus can include a controller having at least one processor coupled with memory. The controller can detect that the output contactor is off causing the output contactor to disconnect from the load. The controller can perform, responsive to the detection, a removal of residual heat from the inverter. The controller can determine whether a temperature of the inverter is not below a threshold from performing the removal of the residual heat. The controller can execute at least one fault countermeasure in accordance with the determination.

In some embodiments, the apparatus can include an input contactor structured to be electrically coupled between the power supply and the inverter. The input contactor can pass the electrical power from the power supply to the inverter. In some embodiments, the controller can detect that the input contactor is off causing the input contactor to disconnect from the power supply. In some embodiments, the controller can perform, responsive to detecting that the input contactor is off, arc extinction to reduce a voltage spike across the input contactor. In some embodiments, the controller can execute the at least one fault countermeasure to deactivate one or more power semiconductor components in the inverter to open a path between an input contactor and the output contactor.

In some embodiments, the apparatus can include a pre-charge contactor structured to be coupled with a direct current (DC) link capacitor coupled with an input of the inverter. The pre-charge contactor can regulate current flowing into the DC link capacitor. In some embodiments, the controller can detect that the pre-charge contactor is off causing the DC link capacitor to disconnect from the power supply. In some embodiments, the controller can determine, responsive to detecting that the pre-charge contactor is off, that an output voltage of the DC link capacitor does not below a threshold voltage. In some embodiments, the controller can perform, responsive to determining that the output voltage does not fall below the threshold voltage, active discharging of the DC link capacitor.

At least one aspect of the present disclosure is directed to a system for controlling deactivation of hotel load converters (HLCs). The system may include a HLC structured to be electrically coupled with a power supply and a load. The HLC may include a plurality of power electronic components. The plurality of power electronic components may include: an inverter structured to be electrically coupled with the power supply and configured to perform direct current to alternating current (DC/AC) conversion on electric power from the power supply; and an output contactor structured to be electrically coupled between the inverter and the load and configured to pass the electric power from the inverter to the load. The system may include a controller structured to be coupled with the HLC. The controller may include a turn-off circuit. The controller may detect that the output contactor is off causing the HLC to disconnect from the load. The controller may remove, responsive to detecting that the output contactor is off, residual heat from the inverter. The controller may determine whether a temperature of the inverter is more than a threshold temperature from performance of the removal of the residual heat. The controller may execute at least one fault countermeasure in the plurality of power electronic components of the HLC, in accordance with the determination.

In some embodiments, the plurality of power electronic components of the HLC may include an input contactor structured to be electrically coupled between the power supply and the inverter. The input contactor may pass the electric power from the power supply to the inverter. The controller may detect that the input contactor is off causing the HLC to disconnect from the power supply. The controller may perform, responsive to detecting that the input contactor is off, an arc extinction to reduce a voltage spike across the input contactor.

In some embodiments, the plurality of power electronic components of the HLC further may include: (i) a DC link capacitor coupled with an input of the inverter and (ii) a pre-charge contactor structured to be coupled with the power supply and the DC link capacitor. The pre-charge contactor may regulate current flowing from the power supply to the DC link capacitor. The controller may detect that the pre-charge contactor is off causing the DC link capacitor to disconnect from the power supply. The controller may determine, responsive to detecting that the pre-charge contactor is off, that an output voltage of the DC link capacitor does not fall below a threshold voltage. The controller may perform, responsive to determining that the output voltage does not fall below the threshold voltage, active discharging of the DC link capacitor.

In some embodiments, the plurality of power electronic components of the HLC may include a rectifier configured to perform alternating current to direct current (AC/DC) conversion on the electric power to generate a plurality of pulse width modulated (PWM) signals. The controller may initiate, at least in partial concurrence with the performance of the removal of the residual heat, shutting down the rectifier. The controller may determine, responsive to initiating the shutting down of the rectifier, that the rectifier continues to generate the plurality of PWM signals. The controller may execute the at least one fault countermeasure, responsive to determining that the rectifier continues to generate the plurality of PWM signals.

In some embodiments, the controller may receive, from a remote device, a command to trigger shutting down of the plurality of power electronic components of the HLC. In some embodiments, the controller may execute, responsive receipt of the command, a turn off sequence to shut down the plurality of power electronic components in the HLC.

In some embodiments, the controller may execute the at least one fault countermeasure to deactivate one or more power electronics components in the HLC to open a connection between an input contactor and the output contactor through the HLC. In some embodiments, the HLC may be disposed on a railway car. The HLC may provide the electric power to the load on the railway car. The load comprises at least one of: an entertainment system, a kitchen appliance, a refrigeration system, or a heating system for the railway car.

At least one aspect of the present disclosure is directed to a controller. The controller may include a turn-off circuit comprising one or more processors coupled with memory. The turn-off circuit may be structured to be coupled with a hotel load converter (HLC) comprising an inverter and an output contactor. The turn-off circuit may detect that the output contactor is off to disconnect the inverter from a load. The turn-off circuit may cause, responsive to detecting that the output contactor is off, a thermal soak to be performed on the inverter to remove residual heat. The turn-off circuit may determine that a temperature of the inverter is greater than a threshold temperature from the performance of the removal of the residual heat. The turn-off circuit may execute at least one fault countermeasure, in response to determining that the temperature of the inverter is greater than the threshold temperature.

In some embodiments, the turn-off circuit may detect that an input contactor is off causing the inverter of the HLC to disconnect from a power supply. In some embodiments, the turn-off circuit may perform, responsive to detecting that the input contactor is off, an arc extinction to reduce a voltage spike across the input contactor.

In some embodiments, the turn-off circuit may detect that a pre-charge contactor is off causing a direct current (DC) link capacitor of the HLC to disconnect from a power supply. In some embodiments, the turn-off circuit may perform, responsive to an output voltage of the DC link capacitor not falling below a threshold voltage, active discharging on the DC link capacitor to prevent current inrush into the inverter.

In some embodiments, the turn-off circuit may determine, at least in partial concurrence with active discharging on a DC link capacitor of the HLC from disconnecting from a power supply via a pre-charge contactor, an output voltage of the DC link capacitor falling below a threshold voltage. In some embodiments, the turn-off circuit may deactivate the inverter to turn off generation of a plurality of pulse width modulated (PWM) signals through the inverter.

In some embodiments, the turn-off circuit may initiate, at least in partial concurrence with the performance of the thermal soak, shutting down a rectifier coupled with the inverter. In some embodiments, the turn-off circuit may execute the at least one fault countermeasure, responsive to determining that the rectifier continues to generate a plurality of PWM signals after a period of time.

In some embodiments, the turn-off circuit may execute, responsive receipt of a command to trigger shut down, a turnoff sequence to shut down the HLC. In some embodiments, the one or more processors and the memory of the turn-off circuit may be disposed in the HLC on a railway car.

At least one aspect of the present disclosure is directed to a method of controlling deactivation of hotel load converters (HLCs). The method may include detecting, by a controller structured to be coupled with a HLC including a output contactor and an inverter, that the output contactor is off to disconnect the inverter from a load. The method may include causing, by the controller, responsive to detecting that the output contactor is off, a thermal soak to be performed on the inverter to remove residual heat. The method may include comparing, by the controller, a temperature of the inverter with a threshold temperature at least in partial concurrence with the removal of the residual heat. The method may include executing, by the controller, at least one fault countermeasure in the HLC, in accordance with comparing the temperature with the threshold temperature.

In some embodiments, the method may include detecting, by the controller, that an input contactor of the HLC is off to disconnect the inverter from a power supply. In some embodiments, the method may include performing, by the controller, responsive to detecting that the input contactor is off, an arc extinction to reduce a voltage spike across the input contactor.

In some embodiments, the method may include detecting, by the controller, that a pre-charge contactor of the HLC is off to disconnect a direct current (DC) link capacitor of the HLC from a power supply. In some embodiments, the method may include preventing, by the controller, responsive to an output voltage of the DC link capacitor not falling below a threshold voltage, current inrush into the inverter by discharging on the DC link capacitor.

In some embodiments, the method may include determining, by the controller, while performing active discharging on a DC link capacitor of the HLC from disconnecting from a power supply via a pre-charge contactor of the HLC, an output voltage of the DC link capacitor falling below a threshold voltage. In some embodiments, the method may include turning off, by the controller, generation of a plurality of pulse width modulated (PWM) signals through the inverter.

In some embodiments, the method may include initiating, by the controller, at least in partial concurrence with the performance of the thermal soak, shutting down a rectifier coupled with the inverter. In some embodiments, executing the at least one fault countermeasure may include executing the at least one fault countermeasure, responsive to determining that the rectifier continues to generate a plurality of PWM signals after a period of time.

In some embodiments, the method may include receiving, by the controller, from a remote device, a command to trigger shutting down of the HLC. In some embodiments, the method may include executing, by the controller, in response to receiving the command, a turnoff sequence to shut down the HLC.

This summary is illustrative only and is not intended to be in any way limiting. Other aspects, inventive features, and advantages of the devices or processes described herein will become apparent in the detailed description set forth herein, taken in conjunction with the accompanying figures, wherein like reference numerals refer to like elements.

### BRIEF DESCRIPTION OF THE FIGURES

FIG. 1 is a perspective view of a railcar including a pantograph and a hotel load converter, according to some embodiments.

FIG. 2 is a perspective view of the hotel load converter of FIG. 1, according to some embodiments.

FIG. 3 is an exploded view of the hotel load converter of FIG. 1, according to some embodiments.

FIG. 4 is a schematic diagram of the hotel load converter of FIG. 1, according to some embodiments.

FIG. 5 is a schematic diagram of a system for controlling deactivation of hotel load converters in hotel load converters according to some embodiments, according to some embodiments.

FIGS. 6A-C are flow diagrams of a method of controlling deactivation of hotel load converters (HLCs), according to some embodiments.

FIG. 7 is a schematic diagram of a pre-charge circuit contactor and a main contactor of the hotel load converter of FIG. 1, according to some embodiments.

### DETAILED DESCRIPTION

Following below are more detailed descriptions of various concepts related to, and implementations of, methods, apparatuses, and systems for systematic deactivation of high power converters and inverters in shutdown and fault events. Before turning to the figures, which illustrate certain exemplary embodiments in detail, it should be understood that the present disclosure is not limited to the details or methodology set forth in the description or illustrated in the figures. It should also be understood that the terminology used herein is for the purpose of description only and should not be regarded as limiting.

Presented herein are systems, apparatuses, devices, and methods for systematic deactivating of high-power, high-voltage inverters and converters. A controller of the inverter and converter can perform various countermeasures in sequence such as a thermal soak (e.g., removal of residual heat), active discharge, decoupling of converter and inverts from sources or loads in combination with fault turn off actions. In this manner, the controller can improve reliability, increase overload capabilities (e.g., rise from 500 kVA to 900 kVA for 3 seconds), reduce number and size of individual components to increase safety of turn off under fault conditions with shutdown acknowledgements.

Regarding the individual processes carried out by the controller, first, the thermal soak procedure can remove residual heat from components of the inverter or the converter, thereby reducing the component's exposures to higher temperature during off conditions, hence much better reliability, lower service call, and reduced maintenance cost. In addition, the components can lower temperature during the next start up size, space, and complexity of components, optimized. For example, using this technique, a hotel load converter (HLC) with a default capability of 500 kVA can be enhanced to deliver 900 kVA for initial 3 seconds.

Second, the active discharge procedure can aid in discharging a direct current (DC) link capacitor with high capacitance (e.g., approximately 25 mF) and high voltage (e.g., 1800 Vdc) within 10 seconds. The activate discharge procedure can rely on the inverter and the internal cooling system without additional external component, thereby reducing or eliminating addition of extra components to carry out other approaches for discharging.

Third, a decoupling procedure of the load and then the source can make the load disconnect first while the source remains connected, thereby facilitating in the performance of the other procedures such as the thermal soak procedure and active discharge. The decoupling procedure can also aid in the reliability of the input contactor, as the input contactor may be always open during no load conditions. Fourth, the fault turn off sequence can be perform to increase the likelihood that the converter follows the fault or emergency shutdown sequence to turn off the inverter and the converter within a set period of time (e.g., a few microseconds) followed by shutdown acknowledgments. Other procedures can be also performed in furtherance of these objectives.

In this manner, the overall high-power converter and inverter can achieve higher reliability, with the thermal soak procedure removing heat from components before each shut down. The converter and inverter can also have higher overload capability (e.g., a 500 kVA converter delivering 900 kVA for first 3 seconds) with thermal soaking operation.

Furthermore, the active discharge procedure can reduce a hazardous 1800V to 50V with 10 seconds without any external components. In addition, the fault turn off sequence to turn off inverter and converter in few micro-seconds and then open input-output contactor, followed by acknowledgements can increase the likelihood of safe turn off.

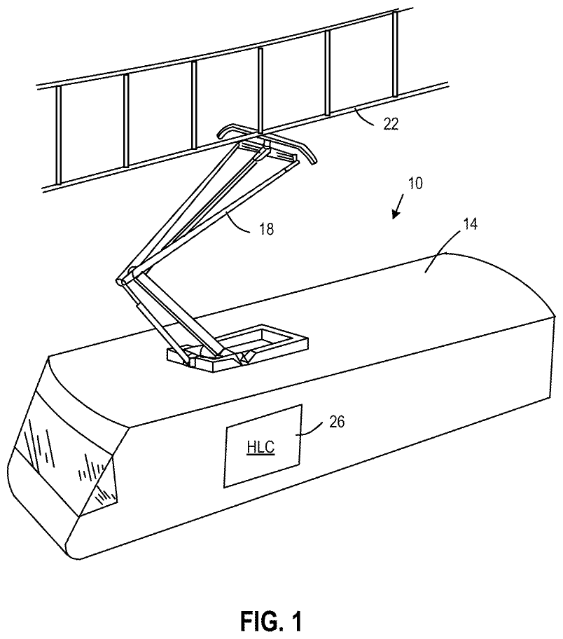

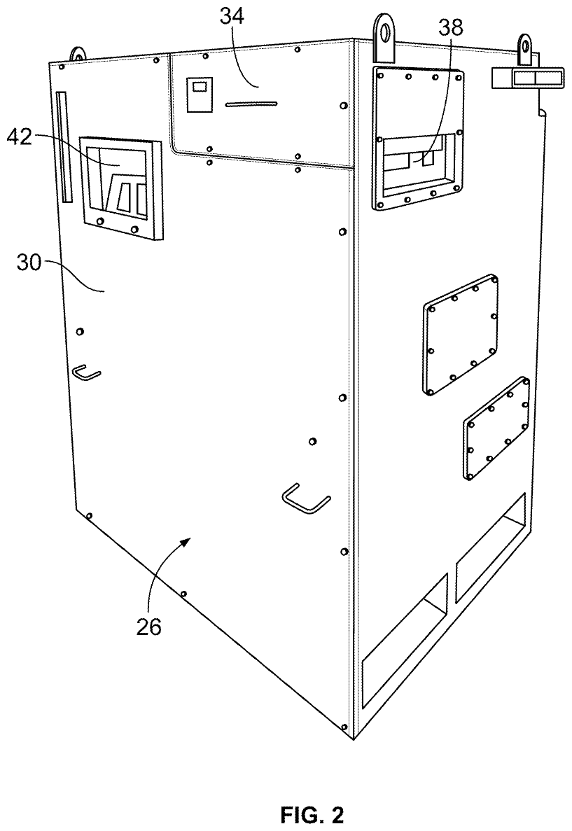

As shown in FIG. 1, a railway car 10 includes a body 14 that supports a pantograph 18. The pantograph 18 includes a set of articulated arms fixed to the body 14 (e.g., a roof) of the railway car 10 that unfold and extend along a vertical axis. A head of the pantograph 18 is fitted with carbon strips structured to engage a contact wire 22. The number and types of carbon strips can be adjusted based on the nature and intensity of the current to be transmitted (e.g., AC or DC). The pantograph 18 transmits power from the contact wire 22 to traction motors and a Hotel Load Converter (HLC) 26.

The HLC 26 is a 500 KW high voltage high power AC to AC converter which has two stages. A first stage converts AC to DC power, and a second stage converts the DC power received from the first stage to three phase AC power. Both the first stage and the second stage include power electronics modules which consists of high power high current insulated-gate bipolar transistor (IGBT) modules, high power bulk capacitors, current and voltages sensors, power electronics, and control boards. The HLC 26 is generally structured to receive power from the pantograph 18 and condition the power for use on the railway car 10 other than to drive the traction motors. For example, the HLC 26 may provide power to climate control (e.g., HVAC), kitchen, washing machines, entertainment systems, lighting, refrigeration systems, water heating systems, etc.

As shown in FIG. 2, the HLC 26 includes a frame 30 structured to support a controller 34 that controls operation of the HLC 26, a connector 38 that provides power from the HLC 26 to external systems of the railway car 10, and a human machine interface (HMI) 42 that allows an operator to interact with the HLC 26.

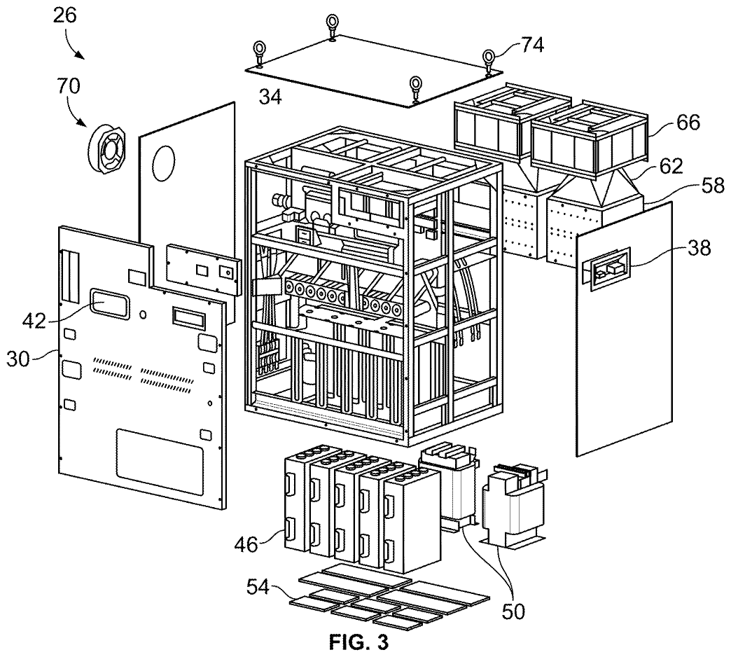

As shown in FIG. 3, the HLC 26 also includes a capacitor bank 46 and inductors 50 supported by bottom plates 54, and a cooling system for the capacitor bank 46 and inductors 50 that includes heat sinks 58, ducts 62, and blowers 66. The HLC 26 also includes a fan 70 for venting the HLC 26 and lifting hooks 74 that facilitate moving the HLC 26. In some embodiments, a different number of capacitors or inductors may be included. Similarly, the number and arrangement of heat sinks 58, ducts 62, and blowers 66 may be adjusted, as desired.

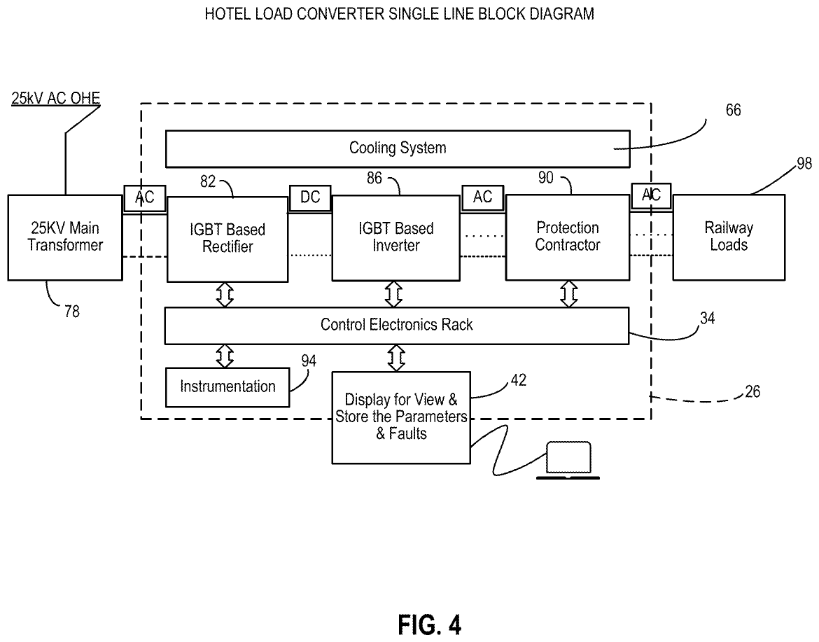

As shown in FIG. 4, the pantograph 18 provides power to a main transformer 78 of the railway car 10 and AC power is provided to the HLC 26. A rectifier 82 receives the AC power from the main transformer 78 and provides DC power to an inverter 86. The inverter 86 can be electrically coupled with the power supply (e.g., the main transformer 78 via the rectifier 82). The inverter 86 converts the DC from the rectifier 82 to three-phase AC power that is provided to a protection contactor 90. The protection contactor 90 is arranged in communication with loads 98 via the connector 38. The controller 34 communicates with and controls the rectifier 82, the inverter 86, and the protection contactor 90. The HLC 26 additionally includes instrumentation 94 (e.g., sensors, shunts, actuators, switches, etc.) in communication with the controller 34. The HMI 42 provides a display and user interface for interaction with the controller 34. In some embodiments, the HMI 42 includes a network connection such as a modem, a network switch, a wireless network, a cloud based service accessible by an application, or another interface, as desired.

In some embodiments, an input voltage received by the rectifier 82 defines a minimum voltage of 633 VAC, a nominal voltage of 960 VAC, and a maximum voltage of 1190 VAC.

In some embodiments, a DC bus voltage output by the rectifier 82 is desirably 1800 VDC. In some embodiments, a line voltage per phase of the three-phase AC output from the inverter 86 is 750 Vrms. In some embodiments, a frequency output of the inverter 86 is 50 Hz. In some embodiments, a voltage output of the inverter 86 is 500 KVA.

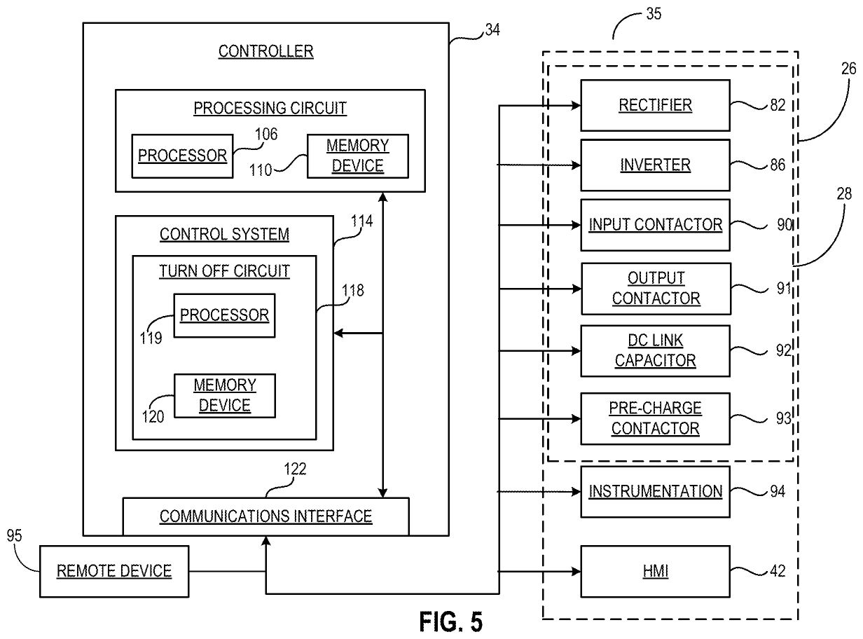

As the components of FIG. 1 are shown to be embodied in the railway car 10, the controller 34 may be separate from or included with at least one railway car controllers located outside the HLC 26. The function and structure of the controller 34 is described in greater detail in FIG. 5.

Referring now to FIG. 5, depicted is a schematic diagram of a system 35 for controlling deactivation of hotel load converters (HLCs). The system 35 may include the controller 34 of the railway car 10 and the HLC 26 and the pantograph 18 of FIG. 1. As shown, the controller 34 includes a processing circuit 102 having a processor 106 and a memory device 110, a control system 114 having a turn-off circuit 118, and a communications interface 122. The turn-off circuit 118 may include at least one or processor 119 and at least one memory device 120, among others. The HLC 26 may include one or more power electronic components 28 (e.g., the rectifier 82, the inverter 86, an input contactor 90, an output contactor 91, a direct current (DC) link capacitor 92, or a pre-charge contactor 93), the instrumentation 94, and HMI 42, among others. Generally, the controller 34 can be structured to gather various measurements from the instrumentation 94 on the components connected therewith, such as the rectifier 82, the inverter 86, and the contactor 90, among others. Using the measurements, the controller 34 can be configured to detect any fault conditions in the HLC 26 and carry out any countermeasures with respect to the components in response to the detection of such fault conditions.

In one configuration, the turn-off circuit 118 are embodied as machine or computer-readable media that is executable by a processor, such as processor 119. As described herein and amongst other uses, the machine-readable media facilitates performance of certain operations to enable reception and transmission of data. For example, the machine-readable media may provide an instruction (e.g., command, etc.) to, e.g., acquire data. In this regard, the machine-readable media may include programmable logic that defines the frequency of acquisition of the data (or, transmission of the data). The computer readable media may include code, which may be written in any programming language including, but not limited to, Java or the like and any conventional procedural programming languages, such as the “C” programming language or similar programming languages. The computer readable program code may be executed on one processor or multiple remote processors. In the latter scenario, the remote processors may be connected to each other through any type of network (e.g., CAN bus, etc.).

In another configuration, the turn-off circuit 118 are embodied as hardware units, such as electronic control units. As such, the turn-off circuit 118 may be embodied as one or more circuitry components including, but not limited to, processing circuitry, network interfaces, peripheral devices, input devices, output devices, sensors, etc. In some embodiments, the turn-off circuit 118 may take the form of one or more analog circuits, electronic circuits (e.g., integrated circuits (IC), discrete circuits, system on a chip (SOCs) circuits, microcontrollers, etc.), telecommunication circuits, hybrid circuits, and any other type of “circuit.”

In this regard, the turn-off circuit 118 may include any type of component for accomplishing or facilitating achievement of the operations described herein. For example, a circuit as described herein may include one or more transistors, logic gates (e.g., NAND, AND, NOR, OR, XOR, NOT, XNOR, etc.), resistors, multiplexers, registers, capacitors, inductors, diodes, wiring, and so on). The turn-off circuit 118 may also include programmable hardware devices such as field programmable gate arrays, programmable array logic, programmable logic devices or the like. The turn-off circuit 118 may include one or more memory devices for storing instructions that are executable by the processor(s) of the turn-off circuit 118.

The one or more memory devices and processor(s) may have the same definition as provided below with respect to the memory device 110 and processor 106. In some hardware unit configurations, the turn-off circuit 118 may be geographically dispersed throughout separate locations in the vehicle. Alternatively and as shown, the turn-off circuit 118 may be embodied in or within a single unit/housing, which is shown as the controller 34.

In the example shown, the controller 34 includes the processing circuit 102 having the processor 106 and the memory device 110. The processing circuit 102 may be structured or configured to execute or implement the instructions, commands, and/or control processes described herein with respect to turn-off circuit 118. The depicted configuration represents the turn-off circuit 118 as machine or computer-readable media. However, as mentioned above, this illustration is not meant to be limiting as the present disclosure contemplates other embodiments where the turn-off circuit 118, or at least one circuit of the turn-off circuit 118, is configured as a hardware unit. All such combinations and variations are intended to fall within the scope of the present disclosure.

The hardware and data processing components used to implement the various processes, operations, illustrative logics, logical blocks, modules and circuits described in connection with the embodiments disclosed herein (e.g., the processor 106) may be implemented or performed with a general purpose single-or multi-chip processor, a digital signal processor (DSP), an application specific integrated circuit (ASIC), a field programmable gate array (FPGA), or other programmable logic device, discrete gate or transistor logic, discrete hardware components, or any combination thereof designed to perform the functions described herein. A general-purpose processor may be a microprocessor, or, any conventional processor, or state machine.

A processor also may be implemented as a combination of computing devices, such as a combination of a DSP and a microprocessor, a plurality of microprocessors, one or more microprocessors in conjunction with a DSP core, or any other such configuration. In some embodiments, the one or more processors may be shared by multiple circuits (e.g., turn-off circuit 118 may comprise or otherwise share the same processor which, in some example embodiments, may execute instructions stored, or otherwise accessed, via different areas of memory). Alternatively, or additionally, the one or more processors may be structured to perform or otherwise execute certain operations independent of one or more co-processors. In other example embodiments, two or more processors may be coupled via a bus to enable independent, parallel, pipelined, or multi-threaded instruction execution. All such variations are intended to fall within the scope of the present disclosure.

The memory device 110 (e.g., memory, memory unit, storage device) may include one or more devices (e.g., RAM, ROM, Flash memory, hard disk storage) for storing data and/or computer code for completing or facilitating the various processes, layers and modules described in the present disclosure. The memory device 110 may be communicably connected to the processor 106 to provide computer code or instructions to the processor 106 for executing at least some of the processes described herein. Moreover, the memory device 110 may be or include tangible, non-transient volatile memory or non-volatile memory. Accordingly, the memory device 110 may include database components, object code components, script components, or any other type of information structure for supporting the various activities and information structures described herein. The turn-off circuit 118 (or the control system 114 of which the turn-off circuit 118 is a part of or the controller 34) is structured to implement a logic as described below.

In some embodiments, the system 34 may also include a remote device 95. The remote device 95 may include one or more processors (e.g., similar to the processor 106 or 119) and memory (e.g., similar to the memory device 110 or 120). The remote device 95 may be associated with an entity operating the railway car in which the HLC 26 resides. For example, the remote device 95 may be a computing device of a railway command or an on-board computing device of the railway car driver. The remote device 95 may be in communication with the controller 34 via the communication interface 122. For example, the remote device 95 may be communicatively coupled with the controller 34 through a wireless network connection. With the communicative coupling, the controller 34 may send, transmit, or otherwise provide information about the HLC 26.

The turn-off circuit 118 of the controller 34 can be configured to deactivate or turn off the inverter 86 of the HLC 26 in response to a condition. The power system or converter system (e.g., as in the HLC 26) can be shut-down in accordance with a defined logic or sequence to avoid failures or degradations to various components of the inverter 86. These components of the inverter 86 can include one or more power semiconductor devices (e.g., IGBTs), direct current (DC) filters, and DC link capacitors, among others, which can be degraded due to shut-down transients, sequence, and residual heat. Other components of the overall HLC 26 that can be affected if the systematic turn on or off sequence is not properly executed can include: an input contactor, a pre-charge contactor, a pre-charge resistor, an IGBT module (e.g., in both inverter 86 and converter), DC link capacitors, an input inductor, a DC filter capacitor, inverter LC filters, and output contactors, among others.

The turn-off circuit 118 of the controller 34 can carry out a normal turn-off sequence. The normal turn-off sequence can be executed once an HLC on command is turn off (e.g., by a railway control) or an HLC reset command is received (e.g., from the railway control). Upon execution, the turn-off circuit 118 can turn off the output contactor. This can disconnect the load of the HLC 26, as the output contactors can be turned-off while the HLC output and the cooling system 66 may be still on. The turn-off circuit 118 (or the processing circuit 102) of the controller 34 can confirm or verify the off status of the output contactor.

With the confirmation, the turn-off circuit 118 can wait for the cooling system 66 to bring all temperature sensors (e.g., instrumentation 94) to read a current ambient temperature of a given range (0° C. to 60° C.+5° C.). The turn-off circuit 118 can concurrently perform thermal soaking, which may take some span of time (e.g., approximately 2 minutes) to allow the temperature readings to come down. Within a set window of time (e.g., 5 minutes) of thermal soaking, if all sensor temperatures are within ±5° C. of the current ambient temperature (except for magnetics), then the turn-off circuit 118 can proceed with the next steps. Otherwise, the turn-off circuit 118 can cause the HMI 42 to display an error (e.g., with the text “cooling system error”) and can move to a fault turn-off logic detailed below.

Continuing on, the turn-off circuit 118 can shut down the pulse width modulation (PWM) pulses of the rectifier 82, with a maximum execution time of a set time period (e.g., 20 ms). The turn-off circuit 118 can proceed to turn off the input contactor, thereby disconnecting the input source to the HLC 26. The processing circuit 102 can verify or confirm that the off status of the mains contactor. Within a set window of time (e.g., 50 ms), the turn-off circuit 118 can proceed to turn off the pre-charge relay. This can aid with clamping spikes because the input contactor can turn off from carrying current. The processing circuit 102 can verify or confirm the off status of the pre-charge contactor. With the verification, the turn-off circuit 118 can monitor the output voltage from the DC link capacitor until the voltage drops below a set threshold (e.g., 50V). When the voltage threshold is satisfied, the turn-off circuit 118 can turn off the PWM pulses from the rectifier 82. The processing circuit 102 can set a flag indicating that the systematic shutdown sequence is successful in the memory device 110.

In addition, the turn-off circuit 118 of the controller 34 can carry out a fault turn-off sequence. The fault turn-off sequence can be executed upon detection of any fault, except for pantograph bounce or DC link over-voltage. In case of an interrupt signal received by the processing circuit 102 of the controller 34, the following sequence can be performed by the controller 34. The turn-off circuit 118 can shut down PWM pulses of the rectifier 82 and the inverter 86. All the IGBT drivers in the inverter 86 or converter can be latched to an off state, and the input and the output contactors can also be latched off for a window of time (e.g., a few microseconds such as less than 10 us with negative bias).

With the shutting down, the arc extinction procedure can be properly carried out by the turn-off circuit 118, because when the input contactor turns off, the arc may be formed across the input contactor. The pre-charge contactor can also bring some resistance (e.g., approximate 33 Qs across the pre-charge contactor, providing the path with the least impedance for breaking the arc voltage. This path can aid the arc extinction significantly and achieve reliability of the input contactor. Subsequently, the processing circuit 102 can verify or confirm the off status of the main contactor. The processing circuit 102 can verify or confirm the off status of the output contactor. The processing circuit 102 can verify or confirm the off status of the pre-charge contactors after a set period of time (e.g., 50 ms). The processing circuit 102 can set a flag indicating that the systematic shutdown sequence (or fault turn-off sequence) is successful in the memory device 110.

The system 35 may include a HLC 26 structured to be electrically coupled with a power supply and a load. The HLC 26 may include a set of power electronic components 28. In some embodiments, the power electronic component 28 may include: an inverter 86 structured to be electrically coupled with the power supply and configured to perform direct current to alternating current (DC/AC) conversion on electric power from the power supply. In some embodiments, the power electronic components 28 may include an output contactor 91 structured to be electrically coupled between the inverter 86 and the load and configured to pass the electric power from the inverter 86 to the load. The system 35 may include a controller 34 structured to be coupled with the HLC 26. The controller 34 may include a turn-off circuit 118. The controller 34 may detect that the output contactor 91 is off to disconnect the HLC 26 from the load. The controller 34 may remove, responsive to detecting that the output contactor 91 is off, residual heat from the inverter 86. The controller 34 may determine whether a temperature of the inverter 86 is more than a threshold temperature from performance of the removal of the residual heat. The controller 34 may execute at least one fault countermeasure in the set of power electronic component 28 of the HLC 26, in accordance with the determination.

In some embodiments, the set of power electronic components 28 of the HLC 26 may include an input contactor 90 structured to be electrically coupled between the power supply and the inverter 86. The input contactor 90 may pass the electric power from the power supply to the inverter 86. The controller 34 may detect that the input contactor 90 is off causing the HLC 26 to disconnect from the power supply. The controller 34 may perform, responsive to detecting that the input contactor 90 is off, an arc extinction to reduce a voltage spike across the input contactor 90.

In some embodiments, the set of power electronic components 28 of the HLC 26 further may include: (i) a DC link capacitor 92 coupled with an input of the inverter 86 and (ii) a pre-charge contactor 93 structured to be coupled with the power supply and the DC link capacitor 92. The pre-charge contactor 93 may regulate current flowing from the power supply to the DC link capacitor 92. The controller 34 may detect that the pre-charge contactor 93 is off causing the DC link capacitor 92 to disconnect from the power supply. The controller 34 may determine, responsive to detecting that the pre-charge contactor 93 is off, that an output voltage of the DC link capacitor 92 does not fall below a threshold voltage. The controller 34 may perform, responsive to determining that the output voltage does not fall below the threshold voltage, active discharging of the DC link capacitor 92.

In some embodiments, the set of power electronic components 28 of the HLC 26 may include a rectifier 82 configured to perform alternating current to direct current (AC/DC) conversion on the electric power to generate a plurality of pulse width modulated (PWM) signals. The controller 34 may initiate, at least in partial concurrence with the performance of the removal of the residual heat, shutting down the rectifier 82. The controller 34 may determine, responsive to initiating the shutting down of the rectifier 82, that the rectifier 82 continues to generate the plurality of PWM signals. The controller 34 may execute the at least one fault countermeasure, responsive to determining that the rectifier 82 continues to generate the plurality of PWM signals.

In some embodiments, the controller 34 may receive, from a remote device 95, a command to trigger shutting down of the set of power electronic components 28 of the HLC 26. In some embodiments, the controller 34 may execute, responsive receipt of the command, a turn off sequence to shut down the set of power electronic components 28 in the HLC 26.

In some embodiments, the controller 34 may execute the at least one fault countermeasure to deactivate one or more power electronics components in the HLC 26 to open a connection between an input contactor 90 and the output contactor 91 through the HLC 26. In some embodiments, the HLC 26 may be disposed on a railway car. The HLC 26 may provide the electric power to the load on the railway car. The load comprises at least one of: an entertainment system 35, a kitchen appliance, a refrigeration system 35, or a heating system 35 for the railway car.

The controller 34 may include a turn-off circuit 118 comprising one or more processors 119 coupled with memory 120. The turn-off circuit 118 may be structured to be coupled with a hotel load converter (HLC 26) comprising an inverter 86 and an output contactor 91. The turn-off circuit 118 may detect that the output contactor 91 is off to disconnect the inverter 86 from a load. The turn-off circuit 118 may cause, responsive to detecting that the output contactor 91 is off, a thermal soak to be performed on the inverter 86 to remove residual heat. The turn-off circuit 118 may determine that a temperature of the inverter 86 is greater than a threshold temperature from the performance of the removal of the residual heat. The turn-off circuit 118 may execute at least one fault countermeasure, in response to determining that the temperature of the inverter 86 is greater than the threshold temperature.

In some embodiments, the turn-off circuit 118 may detect that an input contactor 90 is off causing the inverter 86 of the HLC 26 to disconnect from a power supply. In some embodiments, the turn-off circuit 118 may perform, responsive to detecting that the input contactor 90 is off, an arc extinction to reduce a voltage spike across the input contactor 90.

In some embodiments, the turn-off circuit 118 may detect that a pre-charge contactor 93 is off causing a direct current (DC) link capacitor 92 of the HLC 26 to disconnect from a power supply. In some embodiments, the turn-off circuit 118 may perform, responsive to an output voltage of the DC link capacitor 92 not falling below a threshold voltage, active discharging on the DC link capacitor 92 to prevent current inrush into the inverter 86.

In some embodiments, the turn-off circuit 118 may determine, at least in partial concurrence with active discharging on a DC link capacitor 92 of the HLC 26 from disconnecting from a power supply via a pre-charge contactor 93, an output voltage of the DC link capacitor 92 falling below a threshold voltage. In some embodiments, the turn-off circuit 118 may deactivate the inverter 86 to turn off generation of a plurality of pulse width modulated (PWM) signals through the inverter 86.

In some embodiments, the turn-off circuit 118 may initiate, at least in partial concurrence with the performance of the thermal soak, shutting down a rectifier 82 coupled with the inverter 86. In some embodiments, the turn-off circuit 118 may execute the at least one fault countermeasure, responsive to determining that the rectifier 82 continues to generate a plurality of PWM signals after a period of time.

In some embodiments, the turn-off circuit 118 may execute, responsive receipt of a command to trigger shut down, a turnoff sequence to shut down the HLC 26. In some embodiments, the one or more processors 119 and the memory 120 of the turn-off circuit 118 may be disposed in the HLC 26 on a railway car.

In some embodiments, the controller 34 can determine whether the HLC turn off sequence is to be triggered. If the HLC turn off sequence is triggered (e.g., with a command made by the railway command), the controller 34 can initiate normal turn off logic. The controller 34 can set an output contactor 91 to an off state. The output contactor 91 can be electrically coupled with the inverter 86 and a load of the HLC 26. The output contactor 91 can pass electrical power from the inverter 86 to the load. The off state can disconnect the output contactor 91 from the load. The remainder of the HLC 26 can remain for the following processes for shutdown.

The controller 34 can detect or confirm whether the output contactor 91 is off to disconnect the output contactor 91 from the load. If the output contactor 91 is not confirmed to be off, the controller 34 can determine that there is fault. Otherwise, in response to detection or confirmation that the output contactor 91 is off, the controller 34 can perform a thermal soak. The thermal soak can be to remove the residual heat from the inverter 86. The thermal soak can be used to cool down components of the inverter 86 to an ambient temperature to avoid unnecessary heat exposure when the system is turning off (e.g., including the cooling system turning off). The low temperature exposure can have following benefits. First, the residual heat component heat can be removed from the component, thereby allowing these components to be exposed to lower temperatures before turning off. Second, the in-rush current power handling capability of the inverter 86 can be improved and increased. Third, there may be lower thermal stress for the components of the inverter 86 upon start up and at shut down, thereby bettering the life and increasing the longevity and performance of the components

The controller 34 can determine whether there is a temperature sensor fault. To determine, the controller 34 can determine whether a temperature of the inverter 86 is below a threshold temperature from the performance of the thermal soak. The threshold temperature can within a set range (e.g., ±5° C.) of the ambient temperature. If the temperature is below the threshold, the controller 34 can determine that no fault with temperature sensor. Otherwise, if the temperature is not below the threshold, the controller 34 can determine that there is fault. The controller 34 can perform a measure (e.g., a fault countermeasure as described above or continuing with the normal off procedure) in accordance with the determination.

The controller 34 can determine whether the rectifier 82 shut down timely. When there is no temperature sensor fault, the controller 34 can proceed to shut down the rectifier 82. The controller 34 can shut down pulse width modulation (PWM) pulses from the rectifier 82 within a set execution time (e.g., 20 ms). If the PWM pulses continue after the set execution time, the controller 34 can determine that the rectifier 82 did not shut down timely, and determine fault. Otherwise, if the PWM pulses stop after the set execution time, the controller 34 can determine that the rectifier 82 is shut down timely.

The controller 34 can detect or confirm whether an input contactor 90 is off. The input contactor 90 can be electrically coupled between the power supply and the inverter 82.

The input contactor 90 can pass the electrical power from the power supply (e.g., main transformer 78) to the inverter 82. When in the off state, the input contactor 90 can be disconnected from the power supply. If the input contactor 90 is not confirmed to be off, the controller 34 can determine that there is fault. Otherwise, in response to detection or confirmation that the input contactor 90 is off, the controller 34 can perform an arc extinction. The arc extinction can be to reduce a voltage spike across the input contactor 90. When the input contactor 90 turns off, a voltage spike or arc may form across the input contactor 90, as the pre-charge contactor 94 can bring a resistance (e.g., 33 Ωs) across the input contactor 90. This resistance can provide the path with the least impedance for breaking the arc voltage. This can help arc extinction significantly and can help achieve reliability of the input contactor 90 and the surrounding power components.

Subsequent to the arc extinction, the controller 34 can set the pre-charge contactor 94 relay (sometimes referred herein as the pre-charge contactor 94) to an off state. The pre-charge contactor 94 can be electrically coupled with a direct current (DC) link capacitor 92. The DC link capacitor 92 coupled with an input of the inverter 82, or can be at the input of the inverter 82. The controller 34 can detect or confirm whether the pre-charge contactor 94 is off to disconnect the DC link capacitor 92 from the power supply. The disconnection can prevent the in-rush of high current into the inverter 82. If the pre-charge contactor 94 is not confirmed to be off, the controller 34 can determine that there is fault. Otherwise, in response to detection or confirmation that the output contactor 91 is off, the controller 34 can continue with the normal off sequence and can carry out intelligent active discharge.

The controller 34 can monitor output voltage of the DC link capacitor 92. The controller 34 can determine whether the output voltage falls below a threshold voltage (e.g., to 60V from 1800V within a few seconds). If the output voltage does not fall below the threshold, the controller 34 can continue to monitor and continue with the active discharging of the DC link capacitor 92. Otherwise, when the output voltage falls below the threshold, the controller 34 can determine that the discharging is complete. The controller 34 can turn off the PWM pulses from the inverter 82. The controller 34 can terminate the method from either the normal or fault off sequences.

When any fault condition is detected (e.g., during the turn off sequence), the controller 34 can initiate or execute the fault turn off logic (sometimes herein referred as the fault countermeasure). The fault turn off sequence can be to deactivate one or more semiconductor components (e.g., IGBT modules) in the inverter 82 to open a path between the input contactor 90 and the output contactor 91. This can avoid any uncontrolled electrical current flowing into the inverter 82 to avoid catastrophic failure of components in case of the fault condition.

The controller 34 can shut down PWM pulses of the inverter 82 and the rectifier 86. The controller 34 can open the input contactor 90. The controller 34 can open the output contactor 91. The controller 34 can detect or confirm whether the input contactor 90 is off. When confirmed, the controller 34 can detect or confirm whether the output contactor 91 is off. The controller 34 can perform the arc extinction The performance of the arc extinction can be similar as above. The controller 34 can open the pre-charge contactor 94. The controller 34 can detect or confirm whether the pre-charge contactor 94 is off. The confirmation can be similar as step 174 described above. The controller 34 can terminate the method from either the normal or fault off sequences.

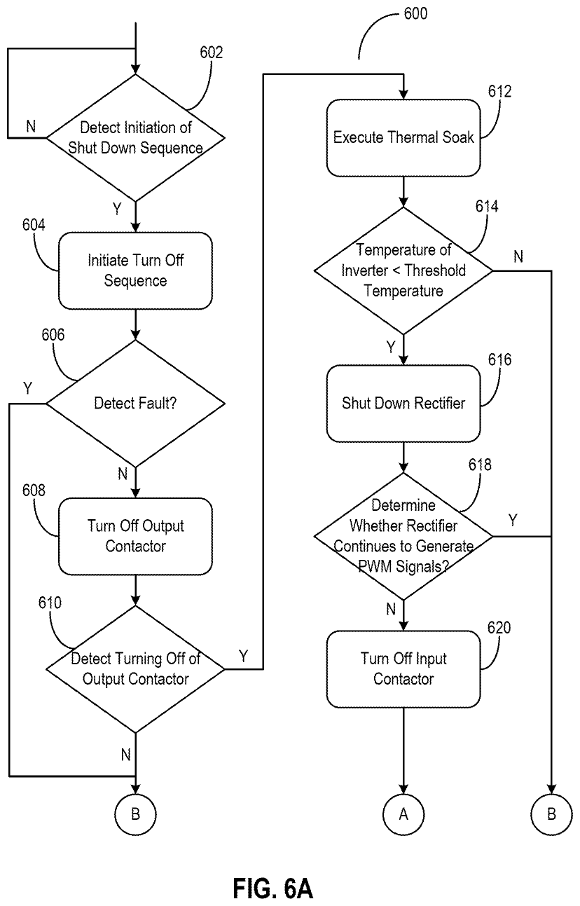

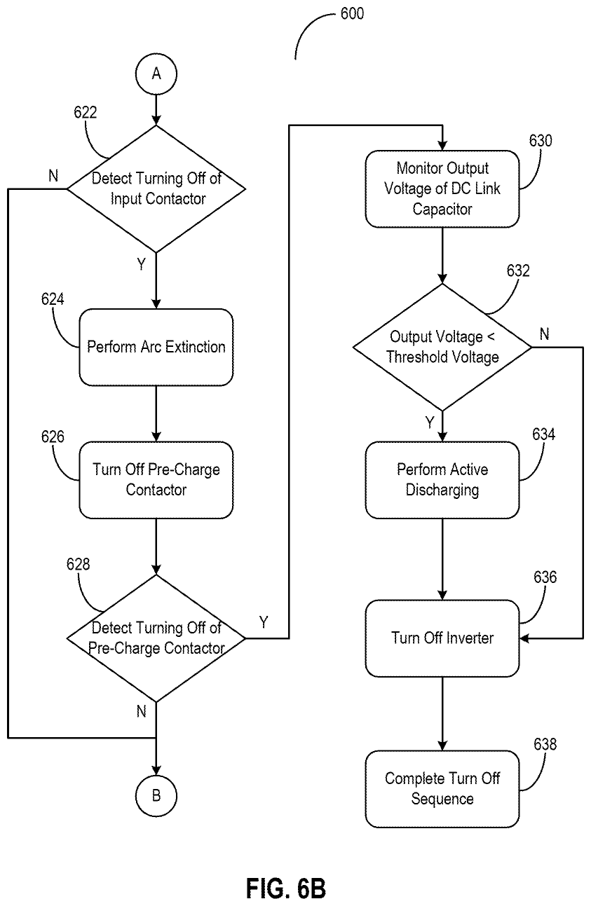

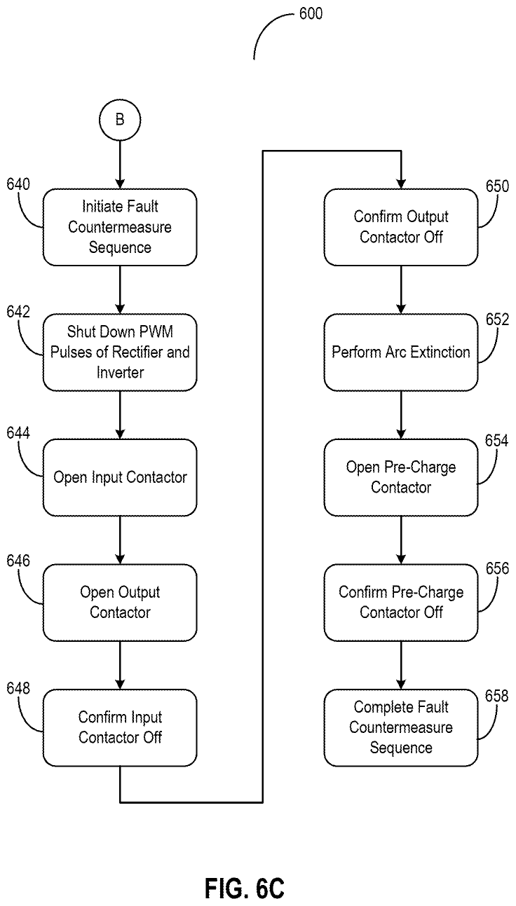

Referring now to FIGS. 6A-C, depicted is a flow diagram of a method 600 of controlling deactivation of the hotel load converter. The method 600 can be implemented or performed using any component as described above, such as the controller 34 or its subcomponents such as the turn-off circuit 118 and the processing circuit 102. Under the method 600, at step 602, a controller may identify, determine, or otherwise detect an initiation of a shutdown sequence for the HLC. The HLC may be electrically coupled with a power supply (e.g., the contactor wire via the pantograph or a battery on the railway car) and a load to convey, deliver, or otherwise provide electric power from the power supply to the load. The HLC may include a set of power electronic components. The power electronic components may include one or more of, for example: an inverter, a rectifier, an input contactor, an output contactor, a pre-charge contactor, and a direct current (DC) link capacitor, among others. To detect, the controller may monitor for a command to trigger shutting down of the HLC. The controller may retrieve, identify, or otherwise receive the command to trigger shutting down of the set of power electronic component of the HLC. Upon receipt of the command, the controller may detect the initiation of the shutdown sequence. If the initiation is not detected, the controller may monitor for the initiation and repeat step 602. In some embodiments, the method 600 may omit the step 602.

At step 604, if the initiation is detected, the controller may begin, start, or otherwise initiate execution of a turn off sequence. In response to receipt of the command to trigger the shutdown, the controller may carry out, perform, or otherwise execute the turn off sequence. The turn off sequence may define or include a series of operations to deactivate, disable, or otherwise turn off the set of power electronic components in the HLC. The turn off sequence may include any one or more of the set of steps 606-638 in any sequence or order, as detailed herein. In some embodiments, the method 600 may include receiving, by the controller, from a remote device, a command to trigger shutting down of the HLC. In some embodiments, the method may include executing, by the controller, in response to receiving the command, a turnoff sequence to shut down the HLC.

At step 606, the controller may identify, determine, or otherwise detect an occurrence of a fault. The HLC may include one or more instrumentation to monitor for faults (e.g., in the form of hardware and software fault monitoring). The fault may correspond to a malfunctioning (e.g., improper functioning) or anomaly (e.g., deviation from expected behavior) of any one or more of the components in the HLC. The fault may include, for example: over-current, over-voltage, frequency deviation, mechanical failures, or sensor failures, among others. If the instrumentation indicates a corresponding fault in the one or more components of the HLC, the controller may detect the occurrence of the fault in the HLC. Upon detection of the fault, the controller may execute at least one countermeasure in the power electronics components of the HLC. Otherwise, if the instrumentation does not indicate a corresponding fault in the one or more components of the HLC, the controller may detect an absence of the fault in the HLC. In some embodiments, the method 600 may omit the step 606.

At step 608, if no fault is detected, the controller may deactivate, open, or otherwise turn off an output contactor. The output contactor may be structured to be coupled between the inverter in the HLC and a load to which the HLC is structured to be coupled. The HLC may convey, deliver, or otherwise provide the electric power to the load on the railway car. The load may include, for example: at least one of: an entertainment system, a kitchen appliance, a personal electronic device, a refrigeration system, or a heating system for the railway car, among others. In some embodiments, the load may include propulsion components in the railway car. The output contactor may deliver, convey, or otherwise pass the electric power from the inverter to the load. To turn off the output contactor, the controller may disconnect or open the connection between the output contactor and the inverter. The controller may disconnect or open the connection between the output contactor and the load. In some embodiments, the method 600 may omit the step 608.

At step 610, the controller may identify, determine, or otherwise detect turning off of the output contactor. To detect, the controller may monitor the electrical parameters in the connection between the output contactor and the load. In some embodiments, the controller may monitor the connection between the output contactor and the inverter in the HLC. Using the electrical parameters, the controller may determine whether electrical power is conveyed through the output contactor. If the electrical power is determined to be conveyed through the output contactor, the controller may determine that the output contactor is not turned off. The controller may also detect the occurrence of the fault in the HLC. Upon detection of the fault, the controller may execute at least one countermeasure in the power electronics components of the HLC. Otherwise, if the electrical power is determined to not conveyed through the output contactor or the electrical power is reduced, the controller may determine that the output contactor is turned off causing the HLC to disconnect from the load. The controller may determine to continue with the turn off sequence.

At step 612, if the output contactor is turned off, the controller may carry out, perform, or otherwise execute a thermal soak to cool or remove residual heat from the inverter. The inverter may be structured to be electrically coupled with the power supply. The HLC may perform direct current to alternating current (DC/AC) conversion on electric power from the power supply. Prior to disconnection, the inverter may have conveyed the converted electric power to the output contactor toward the load. With the detection that the output contactor is off, the controller cause the inverter to perform the thermal soak to transfer heat out of the inverter, thereby cooling the inverter. The residual heat may correspond to heat exceeding an ambient temperature about the HLC (or the inverter in the HLC). The ambient temperature may correspond to a temperature of the surrounding air or environment of the HLC or the inverter. The thermal soak may be performed using a cooling system, such as coolant delivery or application of fans onto the inverter.

At step 614, the controller may determine whether a temperature of the inverter is less than a threshold temperature from performance of the removal of the residual heat. The threshold temperature may correspond to a value of the temperature of the inverter at which to continue the turn off sequence or trigger the countermeasure sequence. The controller may use a sensor (e.g., a thermal sensor or a thermometer) to measure, monitor, or otherwise identify the temperature of the inverter, as the thermal soak is being performed on the inverter. The controller may also use the sensor to measure, monitor, or otherwise the ambient temperature surrounding the HLC (or the inverter). The controller may calculate or determine the threshold temperature based on the ambient temperature (e.g., set with 5% of the ambient temperature).

The controller may compare the temperature of the inverter with the threshold temperature. In some embodiments, the controller may wait for the temperature of the inverter to fall to less than the threshold temperature for a set period of time (e.g., 1-10 minutes). If the temperature of the inverter is greater than the threshold temperature, the controller may determine that the temperature of the inverter is greater than the threshold temperature. The controller may also detect the occurrence of the fault in the HLC. Upon detection of the fault, the controller may execute at least one countermeasure in the power electronics components of the HLC. Conversely, if the temperature of the inverter is less than or equal to the threshold temperature, the controller may determine that the temperature of the inverter is less than or equal to the threshold temperature. The controller may determine to continue with the turn off sequence.

In some embodiments, the method 600 may include detecting, by the controller structured to be coupled with a HLC including a output contactor and an inverter, that the output contactor is off to disconnect the inverter from a load. The method may include causing, by the controller, responsive to detecting that the output contactor is off, a thermal soak to be performed on the inverter to remove residual heat. The method may include comparing, by the controller, a temperature of the inverter with a threshold temperature at least in partial concurrence with the removal of the residual heat. The method may include executing, by the controller, at least one fault countermeasure in the HLC, in accordance with comparing the temperature with the threshold temperature.

At step 616, if the temperature of the inverter is less than the threshold temperature, the controller may disable, turn off, or otherwise shut down a rectifier of the HLC. The rectifier may perform alternating current to direct current (AC/DC) conversion on the electric power to generate a set of pulse width modulated (PWM) signals. The rectifier may be coupled between the power supply via the input of the HLC and the inverter in the HLC. The rectifier may send, convey, or otherwise provide the set of PWM signals to the inverter. In some embodiments, the controller may perform the shutting down of the rectifier, at least in partial concurrence with the performance of the removal of the residual heat from the inverter. To shut down, the controller may disconnect the rectifier from a power source. The controller may also disconnect or open the connection between the inverter and the input of the HLC. The controller may disconnect or open the connection between the inverter and the rectifier.

In some embodiments, the method 600 may include initiating, by the controller, at least in partial concurrence with the performance of the thermal soak, shutting down a rectifier coupled with the inverter. In some embodiments, executing the at least one fault countermeasure may include executing the at least one fault countermeasure, responsive to determining that the rectifier continues to generate a plurality of PWM signals after a period of time. In some embodiments, the method 600 may omit the step 616.

At step 618, the controller may determine whether the rectifier continues to output or generate the set of PWM signals. In some embodiments, the controller may determine whether the rectifier continues to generate the set of PWM signals after a period of time (e.g., milliseconds or seconds). To determine, the controller may monitor the electrical power in the connection between the rectifier and the inverter in the HLC. From monitoring, the controller may determine whether the set of PWM signals is conveyed through the connection from the rectifier to the inverter. If the set of PWM signals is detected in the connection, the controller may determine that the rectifier continues to output or generate the set of PWM signals. The controller may also detect the occurrence of the fault in the HLC. Upon detection of the fault, the controller may execute at least one countermeasure in the power electronics components of the HLC. Otherwise, if the set of PWM signals is not detected in the connection, the controller may determine that the rectifier has ceased outputting or generating the set of PWM signals.

The controller may determine to continue with the turn off sequence. In some embodiments, the method 600 may omit the step 618.

At step 620, if the rectifier ceases to generate the set of PWM pulses from the rectifier (e.g., after the period of time), the controller may disable, open, or otherwise an input contactor. The input contactor may be structured to be electrically coupled between the power supply (e.g., at the input of the HLC) and at least one other power electronic component in the HLC (e.g., the rectifier or the inverter). The input contactor may deliver, convey, or otherwise pass the electric power from the power supply to the at least one other power electronic component (e.g., the rectifier or the inverter). To turn off the input contactor, the controller may disconnect or open the connection between the input contactor and the at least one other power electronic component. The controller may disconnect or open the connection between the input contactor and the power supply.

In some embodiments, the method 600 may include detecting, by the controller, that an input contactor of the HLC is off to disconnect the inverter from a power supply. In some embodiments, the method may include performing, by the controller, responsive to detecting that the input contactor is off, an arc extinction to reduce a voltage spike across the input contactor. In some embodiments, the method 600 may omit the step 620.

At step 622, the controller may identify, determine, or detect whether the input contactor is turned off. To detect, the controller may monitor the electrical parameters in the connection between the input contactor and the power supply. In some embodiments, the controller may monitor the connection between the input contactor and the at least one power electronic component in the HLC. Using the electrical parameters, the controller may determine whether electrical power is conveyed through the input contactor. If the electrical power is determined to be conveyed through the input contactor, the controller may determine that the input contactor is not turned off. The controller may also detect the occurrence of the fault in the HLC. Upon detection of the fault, the controller may execute at least one countermeasure in the power electronics components of the HLC. Otherwise, if the electrical power is determined to not conveyed through the input contactor or the electrical power is reduced, the controller may determine that the input contactor is turned off causing the HLC to disconnect from the power supply. The controller may determine to continue with the turn off sequence. In some embodiments, the method 600 may omit the step 620.

At step 624, if the input contactor is turned off, the controller may execute, carry, or otherwise perform an arc extinction. The arc extinction may be performed on the input contactor to attenuate, suppress, or otherwise reduce a voltage spike across the input contactor. When the input contactor turns off, a voltage spike or arc may form across the input contactor, as other power electronic components (e.g., the pre-charge capacitor) in the HLC can bring a resistance across the input contactor. This resistance can provide the path with the least impedance for breaking the arc voltage. The controller may perform the arc extinction by using at least one of: contact arc suppressor, a solid state relay, or a hybrid power relay, among other. For example, the controller may carry out the arc extinction by apply a magnetic field to the arc between the input contactor and the other power electronic components in the HLC. In some embodiments, the method 600 may omit the step 624.

At step 626, the controller may disable, open, or otherwise turn off the pre-charge contactor. The pre-charge contactor may be structured to be coupled with the power supply and at least one other power electronic component (e.g., the DC link capacitor) in the HLC. The pre-charge contactor may regulate current flowing from the power supply to the power electronic component (e.g., the DC link capacitor). The DC link capacitor may be electrically coupled with an input of the inverter in the HLC. The DC link capacitor may regulate the stability of the inverter in the HLC. To turn off the pre-charge contactor, the controller may disconnect or open the connection between the pre-charge contactor and the at least one other power electronic component (e.g., the DC link capacitor). The controller may disconnect or open the connection between the pre-charge contactor and the power supply. In some embodiments, the method 600 may omit the step 626.

At step 628, the controller may identify, determine, or otherwise whether the pre-charge contactor is turned off. To detect, the controller may monitor the electrical parameters in the connection between the pre-charge contactor and the DC link capacitor. In some embodiments, the controller may monitor the connection between the pre-charge contactor and the DC link capacitor in the HLC. Using the electrical parameters, the controller may determine whether electrical power is conveyed through the pre-charge contactor. If the electrical power is determined to be conveyed through the pre-charge contactor, the controller may determine that the pre-charge contactor is not turned off. The controller may also detect the occurrence of the fault in the HLC. Upon detection of the fault, the controller may execute at least one countermeasure in the power electronics components of the HLC. Otherwise, if the electrical power is determined to not conveyed through the pre-charge contactor or the electrical power is reduced, the controller may determine that the pre-charge contactor is turned off causing the DC link capacitor to disconnect from the power supply. The controller may determine to continue with the turn off sequence. In some embodiments, the method 600 may omit the step 628.

At step 630, if the pre-charge contactor is turned off, the controller may measure, identify, or otherwise monitor an output voltage of the direct current (DC) link capacitor. After the turning off of the pre-charge contactor, the DC link capacitor may release charge in the form out output voltage. The controller may measure the voltage at the output of the DC link capacitor. At step 632, the controller may identify or determine whether the output voltage is less than a threshold voltage. The threshold voltage may delineate, define, or otherwise identify a value for the output voltage at which to trigger the detection of a fault or to continue the turn-off sequence. The threshold voltage may be predetermined based on the capacitance of the DC link capacitor. The controller may compare the output voltage of the DC link capacitor with the threshold voltage. If the output voltage is greater than or equal to the threshold voltage, the controller may determine that the output voltage is greater than or equal to the threshold voltage. Otherwise, if the output voltage is less than the threshold voltage, the controller may determine that the output voltage is less than the threshold voltage. In some embodiments, the method 600 may omit the step 630.

At step 634, if the output voltage is greater than the threshold voltage, the controller may carry out, execute, or otherwise perform active discharging on the DC link capacitor. Subsequent to the disconnection, the DC link capacitor may store electrical charge therein. The controller may draw the electric power stored on the DC link capacitor to reduce the amount of voltage across the DC link capacitor. The controller may activate or switch on an active discharge circuit connected across the DC link capacitor to draw the electric power stored in the DC link capacitor. By performing the active discharging, the controller may prevent current inrush into the inverter by discharging on the DC link capacitor. As the active discharging is performed, the controller may continue to monitor the output voltage of the DC link capacitor, and repeat the functionality from step 632. In some embodiments, the method 600 may omit the step 634.

At step 636, the controller may deactivate, disable, or otherwise turn off the inverter. In some embodiments, with the output voltage of the DC link capacitor falling below the threshold voltage, the controller may deactivate the inverter. By deactivating, the controller may cause ceasing or turning off the generation of the set of PWM pulses through the inverter. At step 638, the controller may finish, terminate, or otherwise complete the turn off sequence. Subsequent to the completion of the turn-off sequence, the controller may reboot, reinitialize, or otherwise restart the power electronic components in the HLC. For example, the controller may receive a command from a remote device to restart the HLC. Upon receipt, the controller may restart the HLC. In some embodiments, the method 600 may omit the step 636 and 638.

In some embodiments, the method 600 may include detecting, by the controller, that a pre-charge contactor of the HLC is off to disconnect a direct current (DC) link capacitor of the HLC from a power supply. In some embodiments, the method 600 may include preventing, by the controller, responsive to an output voltage of the DC link capacitor not falling below a threshold voltage, current inrush into the inverter by discharging on the DC link capacitor.

In some embodiments, the method 600 may include determining, by the controller, while performing active discharging on a DC link capacitor of the HLC from disconnecting from a power supply via a pre-charge contactor of the HLC, an output voltage of the DC link capacitor falling below a threshold voltage. In some embodiments, the method 600 may include turning off, by the controller, generation of a plurality of pulse width modulated (PWM) signals through the inverter.

At step 640, the controller may begin, start, or otherwise initiate a fault countermeasure sequence. In some embodiments, the controller may execute at least one fault countermeasure to deactivate one or more power electronics components in the HLC to open a connection between an input contactor and the output contactor through the HLC. The fault countermeasure sequence may include any one or more of the steps 642-658 as detailed herein, in any sequence or order. Upon detection of the fault from any of steps above, the controller may trigger the execution of at least one of countermeasures in the fault countermeasure sequence in the HLC.

At step 642, the controller may deactivate, disable, or otherwise shut down a set of PWM pulses from the rectifier and the inverter. Step 642 may be similar in functionality to step 616. To shut down, the controller may disconnect the rectifier from a power source. The controller may also disconnect or open the connection between the inverter and the input of the HLC. The controller may disconnect or open the connection between the inverter and the rectifier. In some embodiments, the method 600 may omit the step 642.

At step 644, the controller may disable, turn off, or otherwise open the input contactor. Step 644 may be similar in functionality to step 620. To turn off the input contactor, the controller may disconnect or open the connection between the input contactor and the at least one other power electronic component. The controller may disconnect or open the connection between the input contactor and the power supply. At step 646, the controller may disable, turn off, or otherwise open the output contactor. Step 646 may be similar in functionality in step 608. To turn off the output contactor, the controller may disconnect or open the connection between the output contactor and the inverter. The controller may disconnect or open the connection between the output contactor and the load. In some embodiments, the method 600 may omit the step 644.

At step 648, the controller may check, verify, or otherwise confirm whether the input contactor is turned off. Step 648 may be similar in functionality with step 622. To detect, the controller may monitor the electrical parameters in the connection between the input contactor and the power supply. Using the electrical parameters, the controller may determine whether electrical power is conveyed through the input contactor. If the electrical power is determined to be conveyed through the input contactor, the controller may confirm that the input contactor is not turned off. In some embodiments, the method 600 may omit the step 646.

At step 650, the controller may check, verify, or otherwise confirm whether the output contactor is turned off. Step 650 may be similar in functionality with step 610. To detect, the controller may monitor the electrical parameters in the connection between the output contactor and the power supply. Using the electrical parameters, the controller may determine whether electrical power is conveyed through the output contactor. If the electrical power is determined to be conveyed through the output contactor, the controller may confirm that the output contactor is not turned off. In some embodiments, the method 600 may omit the step 650.

At step 652, the controller may execute, carry out, or otherwise perform the arc extinction. Step 652 may be similar in functionality with step 624. The controller may perform the arc extinction by using at least one of: contact arc suppressor, a solid state relay, or a hybrid power relay, among other. For example, the controller may carry out the arc extinction by apply a magnetic field to the arc between the input contactor and the other power electronic components in the HLC. In some embodiments, the method 600 may omit the step 652.

At step 654, the controller may disable, turn off, or otherwise open the pre-charge contactor. Step 654 may be similar in functionality with step 626. To turn off the pre-charge contactor, the controller may disconnect or open the connection between the pre-charge contactor and the at least one other power electronic component (e.g., the DC link capacitor).

The controller may disconnect or open the connection between the pre-charge contactor and the power supply. In some embodiments, the method 600 may omit the step 654.

At step 656, the controller may check, verify, or otherwise confirm whether the pre-charge contactor. Step 654 may be similar in functionality with step 628. To detect, the controller may monitor the electrical parameters in the connection between the pre-charge contactor and the DC link capacitor. Using the electrical parameters, the controller may determine whether electrical power is conveyed through the pre-charge contactor. If the electrical power is determined to not conveyed through the pre-charge contactor or the electrical power is reduced, the controller may confirm that the pre-charge contactor is turned off causing the DC link capacitor to disconnect from the power supply. In some embodiments, the method 600 may omit the step 656.

At step 658, the controller may complete the fault countermeasure sequence. Subsequent to the completion of the fault countermeasure sequence, the controller may reboot, reinitialize, or otherwise restart the power electronic components in the HLC. For example, the controller may receive a command from a remote device to restart the HLC. Upon receipt, the controller may restart the HLC.

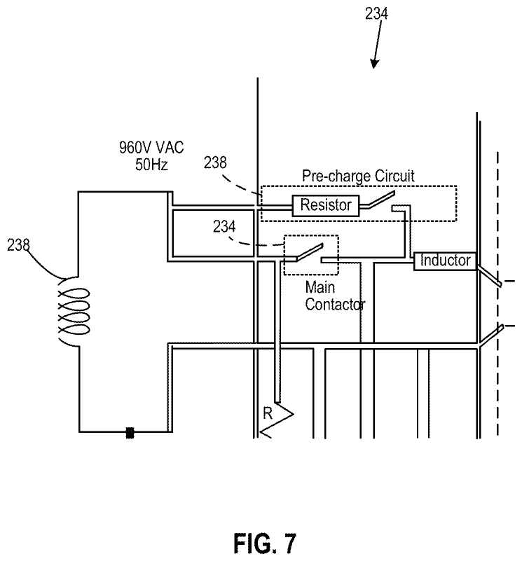

Referring now to FIG. 7, depicted is a schematic diagram of circuitry 226 with a pre-charge circuit contactor 238 and a main contactor 234 of the hotel load converter of FIG. 1. As depicted, in the circuitry 226, both the pre-charge circuit contractor 238 and the main contractor 234 (sometimes herein referred to as an input contactor) can be electrically coupled with an inductor 230. The pre-charge circuit contactor 238 can be used in high power inverter and converter for charging large DC link capacitor to avoid high inrush current and subsequent capacitor and semiconductor premature failures during start up. During high voltage start up (e.g., 630V to 1190V in the HLC), pre-charge contactor circuit 238 can turn on first thereby allowing the large DC link capacitor to be charged with pre-charge resistor in few seconds with limited current to some predefine values. Once the DC link capacitors reached to pre-define values, the mains contactor circuit 234 can turn on to charge the DC link capacitor to full voltage with limited inrush current.

The main contactor circuit 234 of the HLC can very high current (up to 648 arms) during normal operations. To break such high current generally caused high voltage spikes and spark, those sparks and spikes can degrade the contactors and other components life. In order to reduce such spikes to low as possible, the breaking spike or spark can be attenuated by keeping pre-charge contactor circuit 238 in an on state, even if the pre-charge cycle is over. To that end, the pre-charge contactor circuit 238 can have a low-resistance (e.g., between 1-100 Ωs, such as 33 Ωs in the HLC) in parallel with the main contact circuit 234. This may provide for a low-impedance path for high voltage spikes, and can absorb some of the energy in the resistor, thereby lowering the spike and spark compared to no resistor in parallel with the main contact circuit 234.

In high-voltage inverter and converter systems (e.g., a HLC), a DC link capacitor can be charged with a high voltage (e.g., approximately between 1800V and 2000V in HLCs).

Although the inverter or converter can be turned off, the capacitors can remain charged with high voltages for few hours to even whole days. When the system is serviced or handled, a human technician or test engineer can be fatally shocked by the DC link capacitors. Hence, it may be desirable to discharge the capacitors to a safe value (e.g., less than 50V in HLCs) within a short duration (e.g., within a few minutes). There may be multiple techniques to discharge the DC link capacitor in such a system.

Under a passive discharge technique, a permanent resistor can be connected in parallel in parallel with DC link capacitors. These resistors can discharge the capacitor based on resistor values and wattage. For high power converters (e.g., HLC), these resistor may, however, become bulky, costly, decreases the efficiency, continuously dissipating the power, with discharge times close to an hour. The passive discharge technique can call for very large resistor values (e.g., complexity, space, and assembly) and can dramatically reduce system efficiency. It may thus not be practical to use passive resistors in high-power, high-capacitance DC link capacitors (e.g., as with HLC) to discharge within minutes.

Under active discharge technique, the active discharging can be carried out when the inverter and the converter are in an off state, resulting in no continuous power dissipation and no impact to efficiency. The DC link capacitor can be connected with an external resistor and a switching semiconductor. The external switch and resistor can have a size according to the discharge energy and time specifications. The size of external switch and resistors can be comparatively low as these may be active for less than a minute.

To address the drawbacks of both the passive and active discharge techniques, the controller (e.g. the controller 34) can perform intelligent active discharge for inverter and converter systems such as the HLC. Under the intelligent active discharge technique, there may be no reliance on external semiconductor switch or a passive resistor to discharge DC link capacitors. Instead, the inverter and an inductor-capacitor (LC) filter can be used to discharge the DC link capacitor to a safe value by applying the above-described logic. Even with no additional, external components, the DC link capacitor with a capacitance of 25 mF can be discharged from 1800V to less than 50V in approximately 10 seconds.

As utilized herein, the terms “approximately,” “about,” “substantially”, and similar terms are intended to have a broad meaning in harmony with the common and accepted usage by those of ordinary skill in the art to which the subject matter of this disclosure pertains. It should be understood by those of skill in the art who review this disclosure that these terms are intended to allow a description of certain features described and claimed without restricting the scope of these features to the precise numerical ranges provided. Accordingly, these terms should be interpreted as indicating that insubstantial or inconsequential modifications or alterations of the subject matter described and claimed are considered to be within the scope of the disclosure as recited in the appended claims.

It should be noted that the term “exemplary” and variations thereof, as used herein to describe various embodiments, are intended to indicate that such embodiments are possible examples, representations, or illustrations of possible embodiments (and such terms are not intended to connote that such embodiments are necessarily extraordinary or superlative examples).

The term “coupled” and variations thereof, as used herein, means the joining of two members directly or indirectly to one another. Such joining may be stationary (e.g., permanent or fixed) or moveable (e.g., removable or releasable). Such joining may be achieved with the two members coupled directly to each other, with the two members coupled to each other using one or more separate intervening members, or with the two members coupled to each other using an intervening member that is integrally formed as a single unitary body with one of the two members. If “coupled” or variations thereof are modified by an additional term (e.g., directly coupled), the generic definition of “coupled” provided above is modified by the plain language meaning of the additional term (e.g., “directly coupled” means the joining of two members without any separate intervening member), resulting in a narrower definition than the generic definition of “coupled” provided above. Such coupling may be mechanical, electrical, or fluidic. For example, circuit A communicably “coupled” to circuit B may signify that the circuit A communicates directly with circuit B (i.e., no intermediary) or communicates indirectly with circuit B (e.g., through one or more intermediaries).

References herein to the positions of elements (e.g., “top,” “bottom,” “above,” “below”) are merely used to describe the orientation of various elements in the FIGURES. It should be noted that the orientation of various elements may differ according to other exemplary embodiments, and that such variations are intended to be encompassed by the present disclosure.

While various circuits with particular functionality are shown in FIGS. 4-6, it should be understood that the controller 34 may include any number of circuits for completing the functions described herein. For example, the activities and functionalities of the turn-off circuit 118 may be combined in multiple circuits or as a single circuit. Additional circuits with additional functionality may also be included. Further, the controller 34 may further control other activity beyond the scope of the present disclosure.

As mentioned above and in one configuration, the “circuits” may be implemented in machine-readable medium for execution by various types of processors, such as the processor 106 of FIG. 5. An identified circuit of executable code may, for instance, comprise one or more physical or logical blocks of computer instructions, which may, for instance, be organized as an object, procedure, or function. Nevertheless, the executables of an identified circuit need not be physically located together, but may comprise disparate instructions stored in different locations which, when joined logically together, comprise the circuit and achieve the stated purpose for the circuit. Indeed, a circuit of computer readable program code may be a single instruction, or many instructions, and may even be distributed over several different code segments, among different programs, and across several memory devices. Similarly, operational data may be identified and illustrated herein within circuits, and may be embodied in any suitable form and organized within any suitable type of data structure. The operational data may be collected as a single data set, or may be distributed over different locations including over different storage devices, and may exist, at least partially, merely as electronic signals on a system or network.

While the term “processor” is briefly defined above, the term “processor” and “processing circuit” are meant to be broadly interpreted. In this regard and as mentioned above, the “processor” may be implemented as one or more general-purpose processors, application specific integrated circuits (ASICs), field programmable gate arrays (FPGAs), digital signal processors (DSPs), or other suitable electronic data processing components structured to execute instructions provided by memory. The one or more processors may take the form of a single core processor, multi-core processor (e.g., a dual core processor, triple core processor, quad core processor, etc.), microprocessor, etc. In some embodiments, the one or more processors may be external to the apparatus, for example the one or more processors may be a remote processor (e.g., a cloud based processor). Alternatively or additionally, the one or more processors may be internal and/or local to the apparatus. In this regard, a given circuit or components thereof may be disposed locally (e.g., as part of a local server, a local computing system, etc.) or remotely (e.g., as part of a remote server such as a cloud based server). To that end, a “circuit” as described herein may include components that are distributed across one or more locations.

Embodiments within the scope of the present disclosure include program products comprising machine-readable media for carrying or having machine-executable instructions or data structures stored thereon. Such machine-readable media can be any available media that can be accessed by a general purpose or special purpose computer or other machine with a processor. By way of example, such machine-readable media can comprise RAM, ROM, EPROM, EEPROM, or other optical disk storage, magnetic disk storage or other magnetic storage devices, or any other medium which can be used to carry or store desired program code in the form of machine-executable instructions or data structures and which can be accessed by a general purpose or special purpose computer or other machine with a processor. Combinations of the above are also included within the scope of machine-readable media. Machine-executable instructions include, for example, instructions and data which cause a general purpose computer, special purpose computer, or special purpose processing machines to perform a certain function or group of functions.

Although the figures and description may illustrate a specific order of method steps, the order of such steps may differ from what is depicted and described, unless specified differently above. Also, two or more steps may be performed concurrently or with partial concurrence, unless specified differently above. Such variation may depend, for example, on the software and hardware systems chosen and on designer choice. All such variations are within the scope of the disclosure. Likewise, software implementations of the described methods could be accomplished with standard programming techniques with rule-based logic and other logic to accomplish the various connection steps, processing steps, comparison steps, and decision steps.

It is important to note that the construction and arrangement of the apparatus (e.g., HLC 26) as shown in the various exemplary embodiments is illustrative only. Additionally, any element disclosed in one embodiment may be incorporated or utilized with any other embodiment disclosed herein. Although only one example of an element from one embodiment that can be incorporated or utilized in another embodiment has been described above, it should be appreciated that other elements of the various embodiments may be incorporated or utilized with any of the other embodiments disclosed herein.

1. A system for controlling deactivation of hotel load converters (HLCs), comprising:
a HLC structured to be electrically coupled with a power supply and a load, the HLC comprising a plurality of power electronic components including:
an inverter structured to be electrically coupled with the power supply and configured to perform direct current to alternating current (DC/AC) conversion on electric power from the power supply; and
an output contactor structured to be electrically coupled between the inverter and the load and configured to pass the electric power from the inverter to the load; and
a controller structured to be coupled with the HLC, the controller having a turn-off circuit configured to:
detect that the output contactor is off causing the HLC to disconnect from the load;
remove, responsive to detecting that the output contactor is off, residual heat from the inverter;
determine whether a temperature of the inverter is more than a threshold temperature from performance of the removal of the residual heat; and
execute at least one fault countermeasure in the plurality of power electronic components of the HLC, in accordance with the determination.

2. The system of claim 1, wherein the plurality of power electronic components of the HLC further comprises an input contactor structured to be electrically coupled between the power supply and the inverter, the input contactor configured to pass the electric power from the power supply to the inverter;
wherein the controller is further configured to:
detect that the input contactor is off causing the HLC to disconnect from the power supply;
perform, responsive to detecting that the input contactor is off, an arc extinction to reduce a voltage spike across the input contactor.

3. The system of claim 1, wherein the plurality of power electronic components of the HLC further comprises: (i) a DC link capacitor coupled with an input of the inverter and (ii) a pre-charge contactor structured to be coupled with the power supply and the DC link capacitor, the pre-charge contactor configured to regulate current flowing from the power supply to the DC link capacitor; and
wherein the controller is further configured to:
detect that the pre-charge contactor is off causing the DC link capacitor to disconnect from the power supply;
determine, responsive to detecting that the pre-charge contactor is off, that an output voltage of the DC link capacitor does not fall below a threshold voltage; and
perform, responsive to determining that the output voltage does not fall below the threshold voltage, active discharging of the DC link capacitor.

4. The system of claim 1, wherein the plurality of power electronic components of the HLC further comprises a rectifier configured to perform alternating current to direct current (AC/DC) conversion on the electric power to generate a plurality of pulse width modulated (PWM) signals; and
wherein the controller is further configured to:
initiate, at least in partial concurrence with the performance of the removal of the residual heat, shutting down the rectifier;
determine, responsive to initiating the shutting down of the rectifier, that the rectifier continues to generate the plurality of PWM signals; and
execute the at least one fault countermeasure, responsive to determining that the rectifier continues to generate the plurality of PWM signals.

5. The system of claim 1, wherein the controller is further configured to:
receive, from a remote device, a command to trigger shutting down of the plurality of power electronic components of the HLC; and
execute, responsive receipt of the command, a turn off sequence to shut down the plurality of power electronic components in the HLC.

6. The system of claim 1, wherein the controller is further configured to execute the at least one fault countermeasure to deactivate one or more power electronics components in the HLC to open a connection between an input contactor and the output contactor through the HLC.

7. The system of claim 1, wherein the HLC is disposed on a railway car and is further configured to provide the electric power to the load on the railway car, wherein the load comprises at least one of: an entertainment system, a kitchen appliance, a refrigeration system, or a heating system for the railway car.

8. A controller, comprising:
a turn-off circuit comprising one or more processors coupled with memory, the turn-off circuit structured to be coupled with a hotel load converter (HLC) comprising an inverter and an output contactor, the turn-off circuit configured to:
detect that the output contactor is off causing the inverter to disconnect from a load;
cause, responsive to detecting that the output contactor is off, a thermal soak to be performed on the inverter to remove residual heat;
determine that a temperature of the inverter is greater than a threshold temperature from the performance of the removal of the residual heat; and
execute at least one fault countermeasure, in response to determining that the temperature of the inverter is greater than the threshold temperature.

9. The controller of claim 8, wherein the turn-off circuit is further configured to:
detect that an input contactor is off causing the inverter of the HLC to disconnect from a power supply;
perform, responsive to detecting that the input contactor is off, an arc extinction to reduce a voltage spike across the input contactor.

10. The controller of claim 8, wherein the turn-off circuit is further configured to:
detect that a pre-charge contactor is off causing a direct current (DC) link capacitor of the HLC to disconnect from a power supply; and
perform, responsive to an output voltage of the DC link capacitor not falling below a threshold voltage, active discharging on the DC link capacitor to prevent current inrush into the inverter.

11. The controller of claim 8, wherein the turn-off circuit is further configured to:
determine, at least in partial concurrence with active discharging on a DC link capacitor of the HLC from disconnecting from a power supply via a pre-charge contactor, an output voltage of the DC link capacitor falling below a threshold voltage; and
deactivate the inverter to turn off generation of a plurality of pulse width modulated (PWM) signals through the inverter.

12. The controller of claim 8, wherein the turn-off circuit is further configured to:
initiate, at least in partial concurrence with the performance of the thermal soak, shutting down a rectifier coupled with the inverter; and
execute the at least one fault countermeasure, responsive to determining that the rectifier continues to generate a plurality of PWM signals after a period of time.

13. The controller of claim 8, wherein the turn-off circuit is further configured to execute, responsive receipt of a command to trigger shut down, a turnoff sequence to shut down the HLC.

14. The controller of claim 8, wherein the one or more processors and the memory of the turn-off circuit are disposed in the HLC on a railway car.

15. A method of controlling deactivation of hotel load converters (HLCs), comprising:
detecting, by a controller structured to be coupled with a HLC including a output contactor and an inverter, that the output contactor is off causing the inverter to disconnect from a load;
causing, by the controller, responsive to detecting that the output contactor is off, a thermal soak to be performed on the inverter to remove residual heat;
comparing, by the controller, a temperature of the inverter with a threshold temperature at least in partial concurrence with the removal of the residual heat; and
executing, by the controller, at least one fault countermeasure in the HLC, in accordance with comparing the temperature with the threshold temperature.

16. The method of claim 15, further comprising:
detecting, by the controller, that an input contactor of the HLC is off causing the inverter to disconnect from a power supply; and
performing, by the controller, responsive to detecting that the input contactor is off, an arc extinction to reduce a voltage spike across the input contactor.

17. The method of claim 15, further comprising:
detecting, by the controller, that a pre-charge contactor of the HLC is off causing a direct current (DC) link capacitor of the HLC to disconnect from a power supply; and
preventing, by the controller, responsive to an output voltage of the DC link capacitor not falling below a threshold voltage, current inrush into the inverter by discharging on the DC link capacitor.

18. The method of claim 15, further comprising:
determining, by the controller, while performing active discharging on a DC link capacitor of the HLC from disconnecting from a power supply via a pre-charge contactor of the HLC, an output voltage of the DC link capacitor falling below a threshold voltage; and
turning off, by the controller, generation of a plurality of pulse width modulated (PWM) signals through the inverter.

19. The method of claim 15, further comprising initiating, by the controller, at least in partial concurrence with the performance of the thermal soak, shutting down a rectifier coupled with the inverter, and
wherein executing the at least one fault countermeasure further comprises executing the at least one fault countermeasure, responsive to determining that the rectifier continues to generate a plurality of PWM signals after a period of time.

20. The method of claim 15, further comprising:
receiving, by the controller, from a remote device, a command to trigger shutting down of the HLC; and
executing, by the controller, in response to receiving the command, a turnoff sequence to shut down the HLC.
